(19) United States
(12) Patent Application Publication
(10) Pub. No.: US 2026/0285025 A1
(43) Pub. Date: Sep. 24, 2026

(54) FORMING VACUUM CELLS COMPRISING A FIRST SUBSTRATE AND A SECOND SUBSTRATE

(71) Applicant: ColdQuanta, Inc., Boulder, CO (US)

(72) Inventors: Nathaniel William Kabat, Boulder, CO (US); Steven Michael Hughes, Louisville, CO (US)

(73) Assignee: ColdQuanta, Inc., Boulder, CO (US)

(21) Appl. No.: 19/033,922

(22) Filed: Jan. 22, 2025

Related U.S. Application Data
(60) Provisional application No. 63/625,707, filed on Jan. 26, 2024.

(51) Int. Cl. B32B 38/00; B32B 17/06; G01R 29/08

(52) U.S. Cl. CPC B32B 38/0004; B32B 17/06; G01R 29/0885; B32B 2307/7376; B32B 2457/00

(57) ABSTRACT

A method for forming one or more vacuum cells comprising a portion of a first and second substrate comprises: forming layers of a bonding material on first and second surfaces of the first substrate; creating one or more cutouts extending from the first surface to the second surface, wherein each cutout extends through the bonding material; aligning the second substrate to the first substrate; and bonding, the bonding comprising applying, with a bonding structure, a pressure to the bonding material between the first substrate and the second substrate, wherein the bonding structure is configured to prevent an electrical current from flowing from the bonding material on the first surface of the first substrate to the bonding material on the second surface of the first substrate, and applying, while the pressure is applied, a voltage between the bonding material on the first surface of the first substrate and the second substrate.

### CROSS-REFERENCE TO RELATED APPLICATION(S)

This application claims priority to and the benefit of U.S. Provisional Application Ser. No. 63/625,707, entitled “VACUUM CELL ASSEMBLY AND PHOTONIC INTEGRATION,” filed Jan. 26, 2024, the entire disclosure of which is hereby incorporated by reference.

### TECHNICAL FIELD

This disclosure relates to forming vacuum cells comprising a first substrate and a second substrate.

### BACKGROUND

Some atomic systems configured for quantum information and quantum sensing applications comprise vacuum cells. Some vacuum cells can be categorized as: 1) ultra-high vacuum (UHV) cells that can be designed, fabricated, and processed such that the cell can maintain 1E-9 Torr and below, 2) vapor cells which can be designed to hold a macroscopic vapor pressure of atoms or molecules for sensing. Some UHV cells can used in cold-atom applications for quantum information processing and storage. Some vapor cells can be smaller and simpler in their design and construction compared to UHV cells. Some atomic system or vacuum cell designs can optimize factors such as optical addressability and collection. In some examples, vacuum cells or vapor cells can be configured such that atomic or molecular systems contained in the cells can be manipulated or probed by optical waves. In some examples, the process for forming a UHV cell can be similar to forming a vapor cell.

Optical waves can be provided to vapor cells or vacuum cells by photonic-integrated circuits (PICs). In some implementations, photonic-integrated circuits are a scalable platform for the generation, manipulation, and launching of laser light for atomic systems. Some implementations of PICs can offer the ability to miniaturize optical systems from many square feet to a single photonics chip or wafer. Some PIC platforms can be closely integrated with vacuum cells in order to improve stability by eliminating long and free-space beam paths that can cause drift in the overall system and reduce the overall size of the system to enable transportable and deployed quantum sensing or quantum information solutions.

PICs can be constructed through patterned deposition of various materials on silicon substrates. Some PICs can comprise one or more waveguides configured to guide optical waves. In some examples, integrating patterned waveguides in PIC designs can be associated with print-through of the waveguide features to the top surface of a device. Print-through can be detrimental to vacuum cell integration techniques where the cell is attached to the PIC, or where the PIC constitutes a vacuum wall. In both cases, configuring a top surface of the PIC to be flat and devoid of surface topologies such as waveguide print-through can create a suitable surface for bonding processes such as optical contact bonding, anodic bonding, and ultrafast laser bonding.

### SUMMARY

In one aspect, in general, a method for forming one or more vacuum cells comprising at least a portion of a first substrate and at least a portion of a second substrate comprises: forming a layer of a bonding material on a first surface of the first substrate; forming a layer of the bonding material on a second surface of the first substrate; creating one or more cutouts extending from a respective portion of the first surface to a respective portion of the second surface of the first substrate, wherein each cutout of the one or more cutouts extends through the layer of the bonding material deposited on the first surface of the first substrate and through the layer of the bonding material deposited on the second surface of the first substrate; aligning a first surface of the second substrate to the first surface of the first substrate; and bonding the first substrate to the second substrate, the bonding comprising applying, with a bonding structure, a pressure to a portion of the layer of the bonding material between the first surface of the first substrate and the first surface of the second substrate after the aligning, wherein the bonding structure is configured to prevent an electrical current from flowing from the layer of the bonding material on the first surface of the first substrate to the layer of the bonding material on the second surface of the first substrate, and applying, while the pressure is applied, a voltage between the layer of the bonding material on the first surface of the first substrate and the second substrate.

Aspects can include one or more of the following features.

The one or more cutouts are formed by single-point diamond machining.

The bonding material comprises silicon.

The bonding material further comprises dopants.

Forming the layer of bonding material on the respective first surface of the first substrate and second surface of the first substrate comprises physical vapor deposition of the bonding material.

The physical vapor deposition of the bonding material comprises sputter deposition of the bonding material.

Each layer of bonding material on the respective first surface of the first substrate and second surface of the first substrate comprises a thickness that is substantially less than or equal to 400 nm.

The method further comprises applying, prior to forming the layer of the bonding material on the first surface of the first substrate, stress compensation to the first substrate to correct a curvature of the first substrate.

The method further comprises aligning a first surface of a third substrate to the second surface of the first substrate; and bonding the third substrate to the first substrate, the bonding comprising applying, with a bonding structure, a pressure to a portion of the layer of the bonding material between the second surface of the first substrate and the first surface of the third substrate after the aligning of the first surface of the third substrate to the second surface of the first substrate, and applying, while the pressure is applied, a voltage between the layer of the bonding material on the second surface of the first substrate and the third substrate.

Bonding the third substrate to the first substrate is performed in vacuum.

Bonding the third substrate to the first substrate is performed in the presence of a quantum system.

The quantum system comprises a chemical selected from the group consisting of potassium, rubidium, and cesium.

The method further comprises forming, prior bonding the first substrate to the second substrate, a layer of a protective coating on the layer of the bonding material on the first surface of the first substrate.

The protective coating comprises aluminum oxide.

The method further comprises forming, prior to bonding the first substrate to the second substrate, a layer of a protective coating on at least one surface of the first substrate exposed by the one or more cutouts.

The method further comprises etching, prior to bonding the first substrate to the second substrate, one or more channels in the first layer of the bonding material on the first substrate, wherein an end of each channel of the one or more channels extends to an edge of the first substrate.

At least a portion of each channel of the one or more channels is in proximity to a cutout of the one or more cutouts.

In another aspect, in general, a vacuum cell comprises at least a portion of a first substrate and at least a portion of a second substrate, the vacuum cell formed by a method comprising: forming a layer of a bonding material on a first surface of the first substrate; forming a layer of the bonding material on a second surface of the first substrate; creating one or more cutouts extending from a respective portion of the first surface to a respective portion of the second surface of the first substrate, wherein each cutout of the one or more cutouts extends through the layer of the bonding material deposited on the first surface of the first substrate and through the layer of the bonding material deposited on the second surface of the first substrate; aligning a first surface of the second substrate to the first surface of the first substrate; and bonding the first substrate to the second substrate, the bonding comprising applying, with a bonding structure, a pressure to a portion of the layer of the bonding material between the first surface of the first substrate and the first surface of the second substrate after the aligning, wherein the bonding structure is configured to prevent an electrical current from flowing from the layer of the bonding material on the first surface of the first substrate to the layer of the bonding material on the second surface of the first substrate, and applying, while the pressure is applied, a voltage between the layer of the bonding material on the first surface of the first substrate and the second substrate.

Aspects can include one or more of the following features.

The vacuum cell, wherein the method further comprises aligning a first surface of a third substrate to the second surface of the first substrate; and bonding the third substrate to the first substrate, the bonding comprising applying, with a bonding structure, a pressure to a portion of the layer of the bonding material between the second surface of the first substrate and the first surface of the third substrate after the aligning of the first surface of the third substrate to the second surface of the first substrate, and applying, while the pressure is applied, a voltage between the layer of the bonding material on the second surface of the first substrate and the third substrate.

The vacuum cell, wherein the method further comprises applying, prior to forming the layer of the bonding material on the first surface of the first substrate, stress compensation to the first substrate to correct a curvature of the first substrate.

Aspects can have one or more of the following advantages.

Some of the methods disclosed herein can be used to configure vacuum cells in order to facilitate optical addressability of atomic or molecular systems within the vacuum cells.

In some implementations, a vacuum cell can be configured such that each cell wall of the vacuum cell comprises a substrate. Some substrates can comprise glass such that implementations can be referred to as “all-glass vacuum cells.” Some glasses can comprise materials such as borosilicate, quartz, soda lime, aluminosilicate, ceramics (e.g., sapphire), or fused silica. In some examples, all-glass vacuum cells (UHV and vapor) can be advantageous for sensing applications. For example, some bulk silicon cell materials or cells can utilize metallic layers for bonding or cell construction such that the metallic layers can interfere with incident electric fields or cause mechanical stress when undergoing temperature fluctuations due to coefficient of thermal expansion (CTE) mismatch. Furthermore, without using the methods disclosed herein, some vapor cells that are utilized in quantum radio-frequency (QRF) sensing comprise a glass-silicon configuration comprising a silicon body with glass windows bonded on the top and bottom of the interrogation cavity. Such implementations can be associated with a large deleterious effect on the incident RF field arising from the silicon. In contrast, using the methods disclosed herein, use of all-glass cells can avoid these deleterious effects.

In addition, all-glass cells can also facilitate optical addressability of atomic or molecular systems confined in the cell. For example, without using the methods disclosed herein, some vapor cells can only have a single axis of optical interrogation where optical access is provided by a “top” and “bottom” window bonded to the cell body. In contrast, using the methods disclosed herein, all-glass cells can offer the advantage of multiple (up to three) orthogonal axes for optical interrogation.

Some vacuum cells can be tightly integrated with PICs or can comprise a cell wall that contains a PIC. In some implementations, tight integration of PIC substrates with vacuum cells can be beneficial to achieve scalable and stable atomic systems. In some examples, laser light that is generated and manipulated on chip can be launched directly into the vacuum environment without free-space beam paths, bulk optics, and no vacuum cell interfaces to eliminate reflections or aberrations at the free space coupling interface. Additionally, the physics package construction of atomic systems can be simplified by having a single, integrated set of vacuum and photon hardware.

Described examples can be useful for any system or network reliant on global position satellite (GPS) or global navigation satellite system (GNSS) timing signals comprising automatic holdover switching in case of GPS issues, e.g., as backup in financial automated teller machine (ATM) networks and financial institutions, for use in timescales (local, global, or national), for data networks, etc. In addition, described examples can be useful in GNSS based timing applications that comprise back-traceability to onset of issues or real-time switching to a backup timing system.

Other features and advantages will become apparent from the following description, and from the figures and claims.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1A is a schematic diagram of an example cell.

FIG. 1B is a schematic diagram of an example process for configuring cells.

FIGS. 2A-2B are schematic diagrams of an example substrate.

FIGS. 3A-3B are schematic diagrams of example cells.

FIGS. 4A-4B are schematic diagrams of an example cell comprising a PIC.

FIGS. 5A-5B are schematic diagrams of an example cell integrated with a PIC.

FIGS. 5C-5D are schematic diagrams of example cells integrated with PICs.

### DETAILED DESCRIPTION

### Assembly of Vacuum Cells

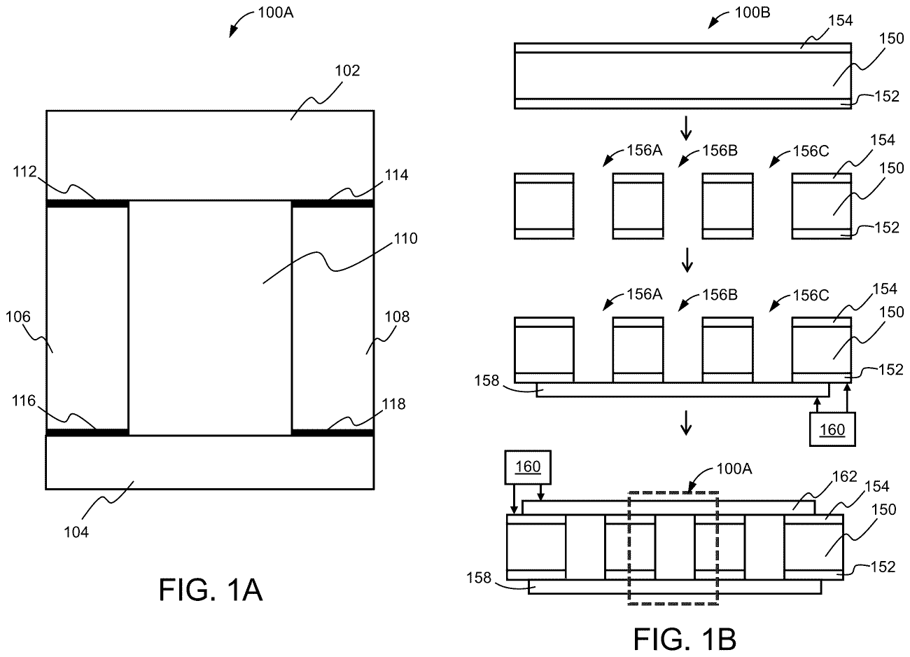

FIG. 1A depicts a cross-section of an example cell 100A comprising a top window 102, a bottom window 104, and side windows 106, 108 enclosing a cell body 110. The top window 102 is bonded to each of the side windows 106, 108 by respective portions of a bonding material 112, 114. The bottom window 104 is bonded to each of the side windows 106, 108 by respective portions of a bonding material 116, 118. In some examples, the side windows 106, 108 can be formed from a substrate. In some examples, a substrate can be referred to as a wafer or chip. In some examples, each of the top window 102, the side windows 106, 108, and the bottom window 104 can comprise glass such that that cell 100A is configured as an “all-glass cell.” In some examples, the cell body 110 can maintain a pressure of 1E-9 Torr and below such that the cell 100A is configured as a vacuum cell. In some examples, the cell body 110 can comprise a macroscopic pressure of gaseous atoms or molecules such that the cell 100A is configured as a vapor cell.

FIG. 1B depicts an example process 100B associated with forming the vacuum cell 100A. The process 100B comprises preparing a first substrate 150. A first layer 152 of a bonding material is formed on a first surface of the first substrate 150 and a second layer 154 of a bonding material is formed on a second surface of the first substrate 150. One or more cutouts 156A-156C are then formed, where each cutout 156A-156C extends from a respective portion of the first surface to a respective portion of the second surface of the first substrate 150. Each cutout 156A-156C also extends through the layer of bonding material 152 on the first surface of the first substrate 150 and the layer of bonding material 154 on the second surface of the first substrate 150. A first surface of a second substrate 158 is aligned to the first surface of the first substrate 150. The second substrate 158 is bonded to the first substrate 150 by applying, with a bonding structure (not shown), a pressure to a portion of the layer of the bonding material 152 between the first surface of the first substrate 150 and the first surface of the second substrate 158. In some examples, the bonding structure can configured to prevent an electrical current from flowing from the layer of the bonding material 152 on the first surface of the first substrate 150 to the layer of the bonding material 154 on the second surface of the first substrate 150. Circuitry 160 is configured to apply, while the pressure is applied by the bonding structure, an electrical current or voltage between the layer of the bonding material 152 on the first surface of the first substrate 150 and the second substrate 158.

The process 100B further comprises a first surface of a third substrate 162 being aligned to the second surface of the first substrate 150. The bonding structure (not shown) can then apply a pressure to a portion of the layer of the bonding material 154 between the second surface of the first substrate 150 and the first surface of the third substrate 162. While the pressure is applied, circuitry 160 applies an electrical current or voltage between the layer of the bonding material 154 on the second surface of the first substrate 150 and the third substrate 162 to form cells including vacuum cell 100A. In some examples, this bonding step can be performed in a vacuum environment such that the bond is formed in the vacuum environment. Some processes can further comprise a dicing step, wherein the respective vacuum cells formed around each of the cutouts 156A-156C are separated from one another.

In some examples, the layer of bonding material 152 and the layer of bonding material 154 can comprise thin-film silicon. Thin-film silicon can be used as a mediating layer to aid in glass-glass bonds. Some implementations of optical contact bonding can be performed with extremely flat (lambda/4 or better) and extremely clean surfaces for successful bonding. Additionally, optical contact bonding performed inside a vacuum environment can comprise internal actuation to position and compress the two components being bonded. Handling of the glass wafers and actuation of components can cause particulates that are detrimental to successful bonding, making in-situ optical contact bonding very difficult.

In some examples, a layer of bonding material can be formed by physical vapor deposition processes such as sputter deposition, thermal evaporation, electron-beam physical vapor deposition, or laser deposition.

In some vapor cell wafer assembly process flows, such as the process shown in FIG. 1B, one step of the process can comprise forming a bond between a glass wafer, i.e., the second substrate 158, and the middle wafer, i.e., the first substrate 150, that is patterned with cell cavities. This bond can be formed in the laboratory environment, i.e., not in a vacuum environment. For the wafer stack depicted in FIG. 1B, which has thin-film silicon on the top and bottom surfaces, i. e, the layers of bonding material 152, 154, of the middle glass wafer, the in-lab bond between the middle and bottom wafers can result in the top film being exposed to atmosphere while at high temperatures. In some examples, this exposure can result in degradation of the top silicon film layer following the first-step bottom window bond. In some examples, bonding processes can be performed at low temperatures in order to minimize the growth of oxides. For instance, bonding processes can be performed at temperatures below 300 C. In addition, an in-vacuum bonding process can be utilized for the first bond and can be associated with reduced reactivity of the top film to contaminants in the atmosphere while at elevated temperatures during the bonding process. A second mitigation path can change the design of the wafer stack, and more specifically the surface that has the thin-film coating, to eliminate any thin-film not playing an active role in a bond existing at elevated temperatures outside of vacuum. The silicon film can be located on any of the glass surfaces to complete these wafer bonding processes and can include polarity control during bonding. In some examples, if a silicon thin film is formed on either of the windows, masking can be used to maintain optical access to the individual cells. In some processes for forming cells, a thin film of silicon can be formed on the top window, i.e., the third substrate 154, rather than the top surface of the middle layer. Removing the silicon film from the middle wafer and placing the film on the top wafer can allow the film to not be heated in atmosphere during the first bond. However, the orientation of the silicon film as the top layer of the bond can result in incompatibility with the flow of charges across the silicon-glass boundary and the standard polarity used when bonding glass on top of silicon. When the top silicon film is re-positioned, the polarity of the bond can be flipped to maintain a consistent flow of charge from the glass into the silicon. In some implementations, one side of the middle wafer can be coated before the first bond and the second side can be coated following the completion of the first bond.

In some examples, the assembly of glass cells can utilize optical contact bonding to provide robust, hermetic seals. In some implementations, anodic bonding can be more forgiving to achieving successful bonds. In examples, glass substrates can be hermetically bonded using a thin film of deposited silicon. In some implementations, the deposited silicon can further comprise dopants such as Group III or Group V elements, including boron, arsenic, phosphorus, antimony, aluminum, and gallium. In some examples, using undoped thin-film silicon can be associated with lowering effects on incident electric fields in applications such as QRF sensing. Some thin films can have thicknesses ranging from 10 nm to 400 nm.

To further strengthen the thin-film anodic bond, and potentially consume the silicon layer, an ultrafast laser welding process can be employed at both the top and bonding interfaces. Laser bonding can be performed at the wafer scale through the top and bottom windows and before the unit cells are diced.

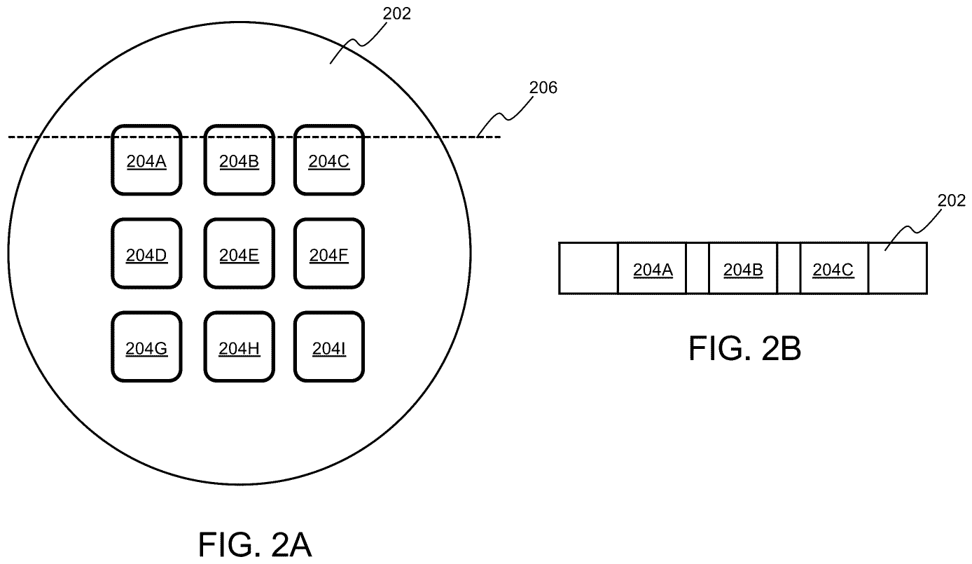

In some examples, a plurality of cutouts can be formed in a wafer such that a process can produce a plurality of vacuum cells. FIG. 2A depicts a top view of a wafer 202 comprising cutouts 204A-204I. FIG. 2B depicts a cross-section view of the wafer 202 along plane 206. In some examples, each of the cutouts 204A-204I can be formed by cell body patterning. Some implementations of cell body patterning in wafers (e.g., CNC machining) can create surfaces that do not have optical surface quality for the clean transmission of visible and near-infrared beams. Alternatively, single-point diamond milling/turning/machining can be utilized to pattern wafers. In some implementations, single-point diamond milling/turning/machining can be applied to the fabrication of mirrors, refractive optics, and mirror-quality metal machining with ~50A surface roughness and Lamda/4 flatness without the need for post-machining lapping or polishing. A machining process able to achieve optical surface quality can enable new functionality for vacuum and vapor cells. Machining internal side-walls of glass, combined with post-dice lapping of external cell surfaces, can create a vapor cell with three orthogonal optical axes. Multiple orthogonal optical axes can be advantageous for improving the sensitivity of optically-pumped magnetometers (OPM), for example. Some applications of single-point diamond machining can create square vapor cells with three orthogonal optical axes.

Some processes for forming all-glass wafer stacks utilizing thin-film silicon can be associated with localized areas containing deleterious build-up of material. In some examples, the localized areas or nucleation spots can be associated with a buildup of sodium ions. This buildup can be caused by having silicon films on both sides of the central wafer such that the films induce a reverse bonding effect and result in sodium ion buildup. In some examples, the build-up can be reduced by controlling the total amount of accumulated charge that is collected across the interface during both bonding steps. For example, sodium buildup can be accelerated with a higher bonding voltage for either (or both) the bottom wafer and top wafer bonds.

Some anodic bonding processes can be associated with generation of oxygen (O₂) from the glass during the execution of the bond. If not properly mitigated, oxygen can be trapped inside the vapor cell. Some quantum sensing applications can utilize vapor cells with extremely pure vapor such that the addition of excess amounts of other gases including helium, nitrogen, oxygen, etc. can degrade the performance of the sensor. In some examples, a vapor cell can contain alkali vapors comprising elements that are chosen from Group 1 of the periodic table such as lithium, sodium, potassium, rubidium, or cesium. In some examples, vapor cells can contain other elements or materials such as iodine, calcium, strontium, mercury, or ytterbium. Additionally, all-glass vapor cells can have a large percentage of glass, which can be a source of oxygen generation, compared to traditional glass-silicon vapor cell assemblies. Therefore, mitigating gaseous contaminants that are trapped inside the cell can be useful to facilitate performance of all-glass cells. One mitigation strategy is to utilize barrier coatings to prevent the liberation of oxygen from glass surfaces. In some implementations, aluminum oxide (Al₂O₃) films deposited with sputter deposition or atomic-layer deposition (ALD) processes can have barrier properties for helium, and can potentially act as a barrier to oxygen. Additionally, anodic bonds can be performed through thin films of Al₂O₃ at the bonding interface. Another mitigation strategy for excess oxygen is to coat all internal and bonding surfaces with a thin film of Al₂O₃. Another possible barrier coating can be accomplished by machining the cavities before silicon deposition such that the resulting silicon coating creates a thin coating on the interior cavities. In some examples, silicon deposition can comprise sputter deposition. In some examples, this thin silicon coating can act as an oxygen barrier or react with generated oxygen. Another mitigation strategy to mitigate oxygen from entering the cell cavity is to define evacuation channels at the bonding interface to allow oxygen to be removed from near the cells. Some patterned channels cannot breach the boundary of individual cells as this breach can prevent the creation of a hermetic cell. Alternatively, channels can be patterned around the unit cells that extend to an edge of the wafers to allow for the oxygen to be pumped by the vacuum pumps inside the bonding chamber.

Some vacuum cells can be integrated photonic integrated circuits (PICs). For instance, some vacuum cells can be configured such that a cell wall comprises a PIC. In some examples, preparing a surface of a PIC can facilitate a robust and high-performance interface between the cell and the light introduced from the PIC. Various examples can reduce the surface topology caused by print-through, other non-ideal flatness and surface features that result from the PIC fabrication. A PIC may be processed using a chemical-mechanical polishing (CMP) process that yields significantly smoother surfaces and can eliminate waveguide print through. Once this has been achieved, various bonding and overcoating processes (in support of bonding) can take place to attach the PIC and vacuum cell together.

### Vacuum Cell Construction With PICS Comprising a Vacuum Wall

In some examples, to make PIC and vacuum cell attachment feasible, the surface of the PIC can first be prepared. Some UHV-compatible bonding processes, such as optical contact bonding and anodic bonding, can include the two surfaces that are very flat such that the surfaces are associated with low surface roughness. Some buried waveguide features that cause print-through, which can result in surface features that are rough. In some examples, print-through can be associated with difficulties in performing some UHV bonding processing. CMP processing can be used to eliminate print-through and prepare a PIC for bonding. Following CMP, native or doped silicon can be grown or deposited via a physical vapor deposition process on the top polished oxide layer to create a compatible interface for anodic bonding. In some examples, the physical vapor deposition process can comprise sputter deposition.

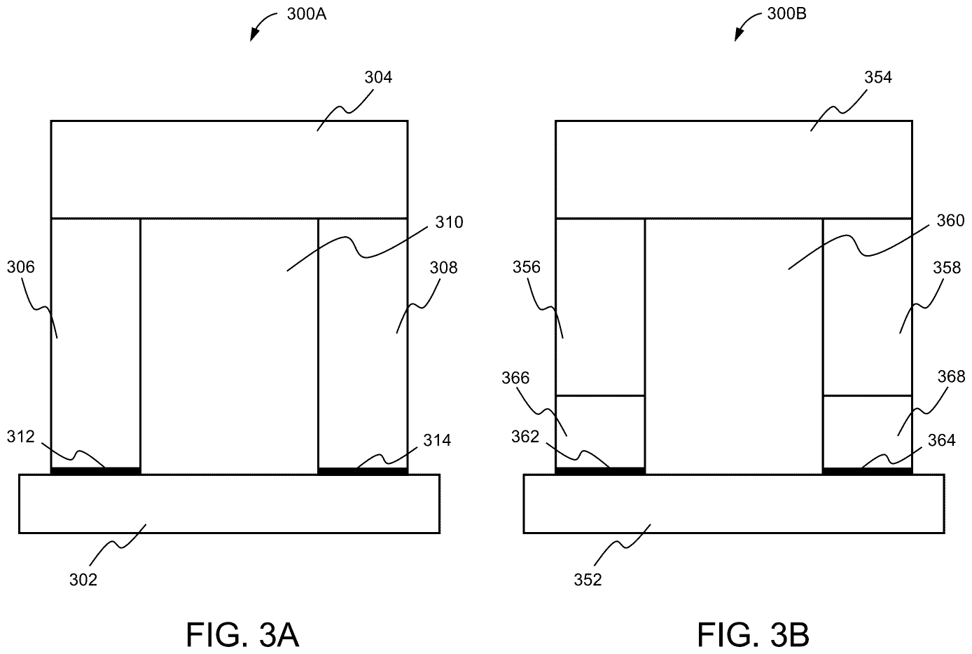

FIG. 3A depicts a cross-section view of an example cell 300A comprising a wall that comprises a PIC 302. The cell 300A comprises a cell window 304 and cell walls 306, 308 enclosing a cell body 310. In this example, the PIC 302 is attached to each of the cell walls 306, 308 by respective contact bonds 312, 314. In some examples, the cell walls 306, 308 can be formed from portions of a substrate, as shown by the process depicted in FIG. 1B.

Some ultra-high vacuum (UHV) cells can comprise PICs with an overcoat of thin-film silicon bonded to a glass interface. Constructing UHV cells can then comprise hermetic anodic bonding between two pieces of glass wherein one piece of glass comprises a surface having a sputter-deposited silicon layer. FIG. 3B depicts a cross-section view of an example cell 300B comprising a PIC 352. The cell 300B comprises cell window 354, cell walls 356, 358, and the PIC 352 enclosing cell body 360. Each of the cell walls 356, 358 are bonded to the PIC 352 by respective anodic bonds 362, 364. The cell walls 356, 358 each comprise a respective layer of overcoat 366, 368. In some examples, these layers of overcoat 366, 368 can comprise silicon. In some examples, to maintain optical access into the cell, silicon deposition may be masked to target only the bonding area.

In some implementations, additional polishing and oxide growth or other material deposition can be used to prepare a surface for optical contact bonding. For instance, a PIC surface can be processed by CMP. In some examples, a CMP processed PIC surface can be sputter-deposited to enable metallic bonding methods such as transient liquid-phase or eutectic bonding. Alternatively, other physical vapor deposition methods can be used to deposit material on the surface. Referring back to FIG. 3B, the vacuum cell 300B can comprise layers of overcoat 366, 368 wherein the overcoat comprises metal.

In some examples, the surface of a PIC can be CMP processed or polished prior to forming the UHV cell. Alternatively, the surface of a PIC can remain unpolished prior to forming the UHV cell. In some examples, silicon coating parameters, such as the thickness of the silicon coating, can be optimized to facilitate performance of a UHV cell. In some examples, a silicon coating having a thickness of at least 400 nm can facilitate hermetic bonding processes. In some examples, excess growth of SiO2 during bonding can be accelerated due to the local concentration of oxygen near the silicon film that can create an oxide layer that fills in the void created around print-through of the underlying waveguides. Similar patterning, print-through processes, and oxide growth brought on by anodic bonding can be utilized to execute oxide patterning for protective barriers, optical coatings, or waveguide patterning.

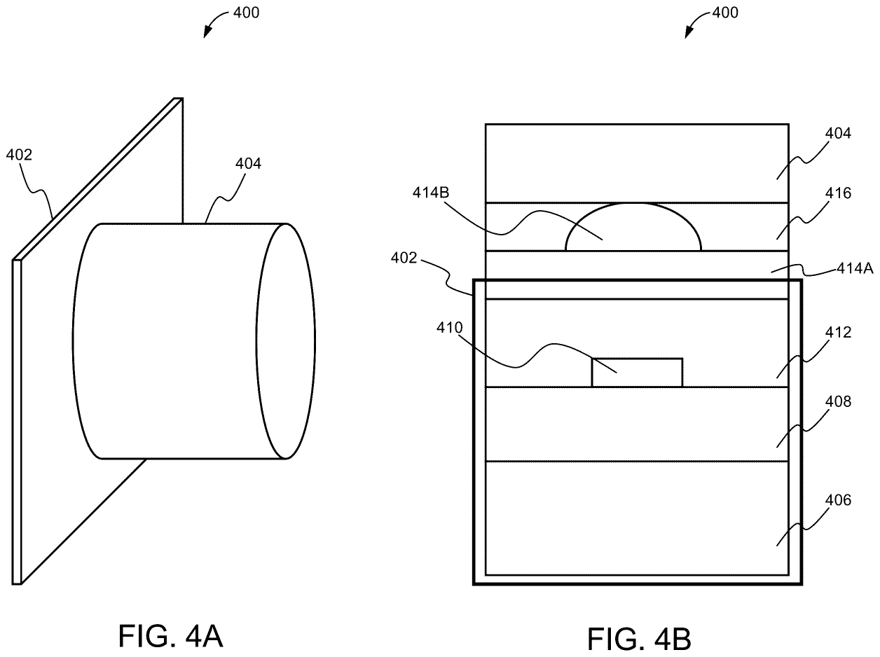

FIG. 4A depicts a perspective view of an example cell 400 comprising a PIC 402 and a body 404. FIG. 4B depicts a cross-section view of the example cell 400. As shown in FIG. 4B, the PIC 402 comprises a first layer 406, a second layer 408, a waveguide 410, and a third layer 412. In some implementations, the first layer 406 can comprise silicon, the second layer 408 and the third layer 412 can each comprise silicon oxide, and the waveguide 410 can comprise silicon nitride. The PIC 402 is bonded to the body 404 by an overcoat 414 comprising a layer 414A and a portion 414B. In some examples, the layer 414A can comprise a thin film of silicon having a thickness. Some thin films can have a thickness of 400 nm. In some examples, gaps between the overcoat 414 can be filled by a material 416. In some examples, the material 416 can comprise silicon or silicon oxide. In some examples, the body 404 can comprise glass such as borosilicate.

In some implementations, stress relieving processes can also be undertaken at the wafer-scale to reduce or mitigate stress that can cause deformation and out-of-flatness across the wafer. In other words, some stress relieving or stress compensating processes can correct for a curvature associated with a wafer. Utilizing top and bottom pre-polished wafers can ensure flatness at the beginning of processing and help improve the flatness of the final assembly. Additionally, techniques such as non-functional waveguide patterning on the top surface of the PIC may be employed to decrease stress at the die and regional level. The same tiling and patterning techniques may be used on the backside of the wafer to help bring the wafer back into flatness. Stress relieving processes can also be undertaken at the wafer-scale to reduce or mitigate stress that can cause deformation and out-of-flatness across the wafer. Utilizing top and bottom pre-polished wafers can ensure flatness at the beginning of processing and help improve the flatness of the final assembly. Additionally, techniques such as non-functional waveguide patterning on the top surface of the PIC may be employed to decrease stress at the die and regional level. The same tiling and patterning techniques may be used on the backside of the wafer to help bring the wafer back into flatness.

### Vacuum/Vapor Cells Attached to PICs

Some PICS that are designed for atomic systems can be larger than the vacuum cells with which they interface. Another system design and assembly process can comprise creating a complete and hermetic vacuum cell (e.g., vapor cell) and attaching the cell to the PIC substrate, similar to a computer processor being attached to a larger circuit board.

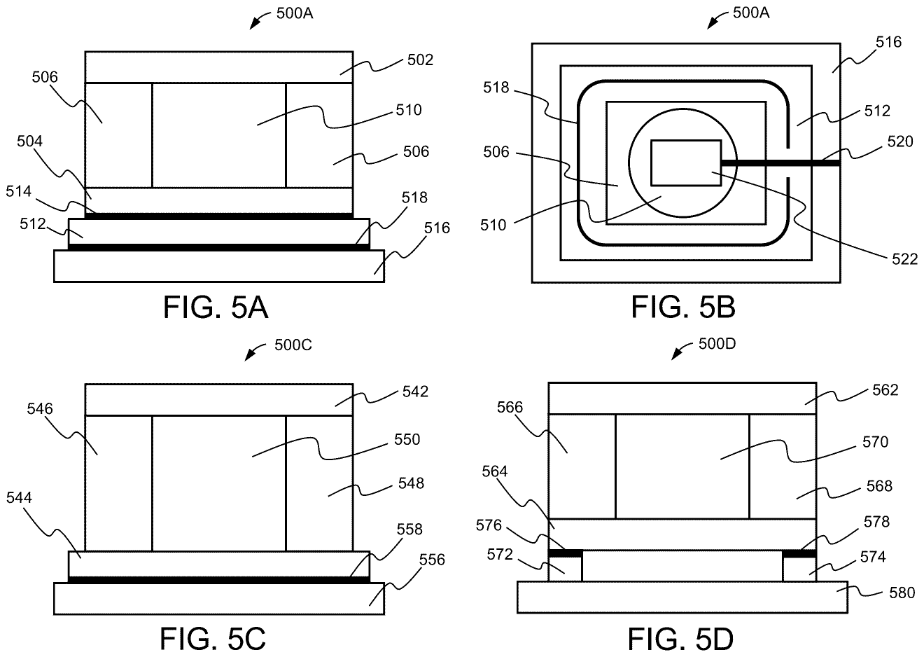

FIG. 5A depicts a cross-section view of an example device 500A comprising cell windows 502, 504 and cell walls 506 enclosing cell body 510. The device 500A comprises a transfer 512 that is connected to the cell window 504 by bond 514. In some examples, the transfer 512 can comprise glass and the bond 514 can be an optical contact bond. The transfer 512 is bonded to a PIC 516 by a bond 518. In some examples, the bond 518 can comprise an optical contact bond or an ultrafast laser bond. FIG. 5B depicts a top view of the example device 500A. As shown in FIG. 5B, the PIC 516 comprises a waveguide 520 connected to an optical element 522. Furthermore, as shown in FIG. 5B, the bond 518 is configured to allow the waveguide 520 to pass through. The top view in FIG. 5B further shows that the cell walls 506 are formed from a substrate.

In some examples, a method of constructing the cell shown in FIGS. 5A, 5B can comprise forming an ultrafast laser bond. In some implementations, using an ultrafast laser to construct a hermetic assembly can be associated with an interaction zone of the laser that can damage the buried waveguide. This interaction zone can present an assembly difficulty since some hermitic assemblies can comprise a closed bonding contour and some grating couplers can have an associated waveguide. Some system assembly processes can be used to construct a complete cell that is optically contacted to the PIC substrate. In some examples, a laser bond can be used to improve the integrity of the attachment without the need to create a closed contour, for instance, using a configuration as shown in FIG. 5D. Additionally, the glass transfer, such as the transfer 512 shown in FIGS. 5A, 5B can be used to aid in the assembly where the cell can be optically contacted to the oversized glass transfer, and the glass transfer contacted and laser bonded to the PIC. In some examples, anodic bonding to a masked silicon overcoat layer, similar to the discussion above, can be employed with a complete cell assembly as well.

In some implementations, a cell can be attached to a PIC such that an optically transparent wall interfaces with a surface grating emitter on the PIC. Referring back to FIG. 5B, in some examples, the optical element 522 can be a surface grating emitter. Some surface grating emitters are waveguide features designed to launch laser light from the PIC and into free space. These grating emitters can be similar to the waveguides themselves such that the grating emitters are patterned features comprising a material such as silicon nitride (SiN). In some examples, these grating emitters can also result in print-through to the top surface.

Some cell configurations can omit the transfer. FIG. 5C depicts a cross-section view of a cell 500C comprising cell windows 542, 544 and cell walls 546, 548 enclosing cell body 550. In some examples, the cell walls 546, 548 can be portions of a single substrate, similar to the configuration shown in FIG. 5B. The cell 500C comprises PIC 556 that is bonded to cell window 544 by bond 558.

Some cell configurations can comprise an overcoat attachment. FIG. 5D depicts a cross-section view of a cell 500D comprising cell windows 562, 564 and cell walls 566, 568 enclosing cell body 570. In some examples, the cell walls 566, 568 can be portions of a single substrate, as shown in FIG. 5B. The cell 500D further comprises mounting substrate comprising portions 572, 574 that are each bonded to the cell window 564 by respective bonds 576, 578. In some examples, these bonds 576, 578 can be anodic bonds. The portions 572, 574 can comprise an overcoat and some overcoats can comprise silicon. The portions 572, 574 are attached to PIC 580.

As discussed above, surface preparation can be employed to improve cell-to-PIC attachment, but for optical and mechanical robustness rather than hermeticity. Special care can be taken during surface preparation to preserve the features of the underlying grating coupler and waveguides while also providing a clean and smooth surface for the vacuum cell interface. Good optical contact with minimal stress between the PIC and the vacuum cell can be useful for minimizing optical aberrations, losses, and other deleterious effects as the light exits from or is inserted to the PIC.

Similar preparation methods as discussed above can be used to prepare the PIC surface for cell attachment. Polishing the top surface can potentially influence the function of the grating emitter since the amount of material removed at the top surface can be more than 10x smaller than the distance between the top surface and the patterned waveguide/grating emitter structure. Therefore, diffraction phenomena caused by the grating resulting in the beam launch can be affected. Some completely hermetic cells can be optically and mechanically attached to the PIC as shown in FIGS. 5C, 5D such that an attachment method does not have to satisfy any hermeticity requirements between the cell and the PIC. Similar surface preparation using CMP can be employed. Since the cell is already bonded together, non-UHV compatible attachment methods such as index-matched UV epoxy can be employed once the substrate has been properly prepared. In various examples, the preparation of the substrate can be accomplished when using epoxy. Some grating couplers can comprise tightly spaced features which can prevent the epoxy from filling all the voids. This prevention can be both detrimental to the quality of the mechanical attachment and to the optical performance of the coupler due to random and uncontrolled pockets at various indices of refraction.

CMP preparation of PICs can be utilized to improve the viability of hermetic bonding. In some examples, non-CMP'ed PICS can also be hermetically bonded. For instance, some PICS that exhibit waveguide print-through can undergo deposition of Si at a few hundred nanometers such that a glass sample can be subsequently anodically bonded to the PIC. Although these assemblies can numerous opportunities for leak-paths to the vacuum cavity, hermeticity can still be achieved. In some examples, voids can be filled by an oxide growth mechanism on the silicon during anodic bonding or reflow/smoothing of silicon during anodic bonding to “remove” print-through.

Vapor cells may also be integrated into the PIC assembly where light is not injected into the cell directly from the grating emitter, but rather, routed from an optic that receives the light from the PIC and directs the light through the cell. In this design, an optic such as a prism mirror or some other type of reflecting or diffracting element may be mounted to the PIC surface utilizing the methods discussed above, or a simple epoxy attachment with active alignment (discussed below), where the cell might not interface with the PIC mechanically, but rather a separate mounting substrate that is under the PIC and accessed through a cut-out in the PIC. The mounting substrate may be a thermal bath (with suitable isolation from the PIC) to provide thermal control of the vapor cell (sometimes operated in the 50-120 C temperature range) and therefore minimize thermal gradients at the PIC attachment interface.

A simpler alternative to the complex methods discussed above can utilize epoxy on a non-polished or otherwise modified PIC surface and may exhibit optical performance without any degradation. The waveguide and grating emitter structure print-through can be on the order of ~100 nm. A cell or an optic that is bonded to the PIC with small amounts of epoxy (beads) on a few specific locations, and not spread across the entire interfacing surface, can keep the optic or cell positioned just a few um off the surface of the PIC. This separation can allow for position and rotation alignment before executing the epoxy cure, as opposed to registering the optic against the PIC and therefore constraining the adjustability of position and rotation. In some examples, pick-and-place robotics, such as hybrid hexapods, can be utilized to hold the optic or cell in place while the epoxy cures.

### Application of PIC Preparation Techniques to Metasurfaces for Vacuum Cell Integration

Some vacuum cells or PICs can comprise metasurfaces. Some metasurfaces are wavelength or sub-wavelength scale structures that are etched and/or printed on a substrate. The ensemble of structures can interact with an incident optical beam and collectively result in phenomena such as anti-reflection, high-reflection, lensing, and retro-reflection. The design of individual structures and the collective pattern can determine the resulting optical effect. Since the structures are so small, they can be incredibly fragile and can be damaged or become contaminated easily. Similar to waveguide print-through discussed above, patterned structures in metasurfaces are not conducive to the bonding techniques discussed above. Therefore, special preparation of the bonding surface can be executed.

In some examples, the CMP and overcoating techniques discussed in PIC preparation for bonding could enable compatibility with metasurfaces. An example process flow is: conformally coat metasurface substrate with several microns of an overcoat layer (e.g., silicate, SiO₂, etc.), CMP polish metasurface structure print-through to arrive a smooth, planar top surface, overcoat (if necessary) with an additional material for bonding compatibility such as silicon, anodically bond the metasurface to the cell. The metasurface can be used as a structural wall of the vacuum cell, or be attached to the outside of the cell.

The metasurface may require changes in structure layout or feature size to avoid the overcoat impacting functionality of the metasurface from the air-interface. This impact can take the form of a redesign of the metasurface features if the overcoat layer impedes the volume of the metasurface itself. If the overcoat is air-gapped from the metasurface volume, considerations can still be taken for the pressure and deformity caused in the overcoat bonding stressors. Additionally, the metasurface may be sealed off by application of a multi-functional, non-metasurface layer that also impacts the light interactions, such as impacting the polarization, beam profile, or other features. Two metasurfaces may be stacked in some cases to enable improved modularity of the constituent parts bonded to prepare the metasurface for interfacing with the vacuum cell.

In the application of vacuum cell design and construction, metasurfaces can be designed to serve multiple functions that are optical or mechanical in nature. Described below are example multifunction uses of metasurfaces. Metasurface design that simultaneously acts as a high reflector (HR) for one wavelength of light, and an anti-reflector (AR) for another wavelength of light. Metasurface design that simultaneously acts as a high reflector (HR) for one wavelength of light, and an anti-reflector (AR) with lensing for another wavelength of light. Metasurface design that simultaneously deflects one wavelength of light from the incident angle while transmitting another wavelength of light undeflected. Metasurface (if not overcoated) that acts as a hydrophobic barrier to prevent alkali condensation, for example in the optical beam path where condensation is detrimental to optical performance. Metasurface that simultaneously polarizes the light for one wavelength of light by produces no effect or scrambles the polarization for another wavelength. Metasurface that simultaneously produces a more uniform polarization of the transmitted light but scrambles the polarization of light incident on the metasurface from within the attached vacuum cell. Metasurfaces that rotate the polarization of the light by a fixed amount for specific wavelengths but may intentionally produce different impacts for different wavelengths or input polarizations. Metasurface that provide smoothing or evening of the light, such as forming a top hat profile or other beam shape that impacts collimation of the output beam or intentionally cases the beam profile to evolve in a way that makes it either more or less compatible with a secondary PIC interface. For example, a top-hat profile beam can have a very uniform intensity profile that can form non-Gaussian shapes like squares or lines. This profile may have the additional benefit of simultaneously reducing scatter light coupling back into the emitting surface or avoiding of coupling of this light into a PIC on the opposite side of the vacuum cell, such as in retroreflected or multiple overlapping beam laser-interrogation geometries.

Metasurfaces may be combined with external fields to control the multi-functionality and turn it on or off. Examples of this control may include a metasurface coupled with a thin film PZT or similar actuator that can provide mechanical stresses on the metasurface in a controlled or uncontrolled manner. An external magnetic field may be applied with a solenoid, electric current, or stationary magnet to enhance or reduce the effectiveness of the metasurface. In this way, a metasurface can function as a selective AR or HR coating, polarization purifier or scrambler, or beam shaping tool.

Metasurfaces may contain multiple ‘zones’of effect on a single surface. A PIC phased array grating output coupler may be able to selectively send transmitted light through specific areas on the grating, imparting different effects to the passed light. The directionality of the beam from the PIC could either be in the form of a binary switch, sending light through section A or section B of the metasurface, where A and B are discrete, whole regions. The metasurface may be designed in another way, wherein regions A and B are intermixed and the output coupler from the PIC intentionally produces structured forms of the light, such as an array of gaussian beams, a checkerboard pattern, concentric rings, etc. Having the differing metasurface regions intermixed can impact the additional benefit of the light-matter interactions in the vacuum cell occurring in effectively the same spatial region relative to a macro-scale photodetector or other receiver structure. In this way, two (or more) discrete functions can be built into the metasurface and selected based on the spatial distribution of the input light, which can be carefully controlled or tuned by choice in the PIC output coupler or with an additional metasurface prior to the selection metasurface. This additional interface may allow amplification of the spatial, polarization, or wavelength differential response properties of the subsequent metasurfaces. Regions need not be limited to simple binary choices, but could extend to include a wide array of choices A, B, C, etc. Regions may apply selective filtering of response by wavelength, polarization, intensity, spatial extent, or other such mechanisms defining the incident beams.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A method for forming one or more vacuum cells comprising at least a portion of a first substrate and at least a portion of a second substrate, the method comprising:
forming a layer of a bonding material on a first surface of the first substrate;
forming a layer of the bonding material on a second surface of the first substrate;
creating one or more cutouts extending from a respective portion of the first surface to a respective portion of the second surface of the first substrate, wherein each cutout of the one or more cutouts extends through the layer of the bonding material deposited on the first surface of the first substrate and through the layer of the bonding material deposited on the second surface of the first substrate;
aligning a first surface of the second substrate to the first surface of the first substrate; and
bonding the first substrate to the second substrate, the bonding comprising
applying, with a bonding structure, a pressure to a portion of the layer of the bonding material between the first surface of the first substrate and the first surface of the second substrate after the aligning, wherein the bonding structure is configured to prevent an electrical current from flowing from the layer of the bonding material on the first surface of the first substrate to the layer of the bonding material on the second surface of the first substrate, and
applying, while the pressure is applied, a voltage between the layer of the bonding material on the first surface of the first substrate and the second substrate.

2. The method of claim 1, wherein the one or more cutouts are formed by single-point diamond machining.

3. The method of claim 1, wherein the bonding material comprises silicon.

4. The method of claim 3, wherein the bonding material further comprises dopants.

5. The method of claim 1, wherein forming the layer of bonding material on the respective first surface of the first substrate and second surface of the first substrate comprises physical vapor deposition of the bonding material.

6. The method of claim 5, wherein the physical vapor deposition of the bonding material comprises sputter deposition of the bonding material.

7. The method of claim 1, wherein each layer of bonding material on the respective first surface of the first substrate and second surface of the first substrate comprises a thickness that is substantially less than or equal to 400 nm.

8. The method of claim 1, further comprising applying, prior to forming the layer of the bonding material on the first surface of the first substrate, stress compensation to the first substrate to correct a curvature of the first substrate.

9. The method of claim 1, further comprising aligning a first surface of a third substrate to the second surface of the first substrate; and
bonding the third substrate to the first substrate, the bonding comprising
applying, with a bonding structure, a pressure to a portion of the layer of the bonding material between the second surface of the first substrate and the first surface of the third substrate after the aligning of the first surface of the third substrate to the second surface of the first substrate, and
applying, while the pressure is applied, a voltage between the layer of the bonding material on the second surface of the first substrate and the third substrate.

10. The method of claim 9, wherein bonding the third substrate to the first substrate is performed in vacuum.

11. The method of claim 9, wherein bonding the third substrate to the first substrate is performed in the presence of a quantum system.

12. The method of claim 11, wherein the quantum system comprises a chemical selected from the group consisting of potassium, rubidium, and cesium.

13. The method of claim 1, further comprising forming, prior bonding the first substrate to the second substrate, a layer of a protective coating on the layer of the bonding material on the first surface of the first substrate.

14. The method of claim 13, wherein the protective coating comprises aluminum oxide.

15. The method of claim 1, further comprising forming, prior to bonding the first substrate to the second substrate, a layer of a protective coating on at least one surface of the first substrate exposed by the one or more cutouts.

16. The method of claim 1, further comprising etching, prior to bonding the first substrate to the second substrate, one or more channels in the first layer of the bonding material on the first substrate, wherein an end of each channel of the one or more channels extends to an edge of the first substrate.

17. The method of claim 16, wherein at least a portion of each channel of the one or more channels is in proximity to a cutout of the one or more cutouts.

18. A vacuum cell comprising at least a portion of a first substrate and at least a portion of a second substrate, the vacuum cell formed by a method comprising:
forming a layer of a bonding material on a first surface of the first substrate;
forming a layer of the bonding material on a second surface of the first substrate;
creating one or more cutouts extending from a respective portion of the first surface to a respective portion of the second surface of the first substrate, wherein each cutout of the one or more cutouts extends through the layer of the bonding material deposited on the first surface of the first substrate and through the layer of the bonding material deposited on the second surface of the first substrate;
aligning a first surface of the second substrate to the first surface of the first substrate; and
bonding the first substrate to the second substrate, the bonding comprising
applying, with a bonding structure, a pressure to a portion of the layer of the bonding material between the first surface of the first substrate and the first surface of the second substrate after the aligning, wherein the bonding structure is configured to prevent an electrical current from flowing from the layer of the bonding material on the first surface of the first substrate to the layer of the bonding material on the second surface of the first substrate. and
applying, while the pressure is applied, a voltage between the layer of the bonding material on the first surface of the first substrate and the second substrate.

19. The vacuum cell of claim 18, wherein the method further comprises
aligning a first surface of a third substrate to the second surface of the first substrate; and
bonding the third substrate to the first substrate, the bonding comprising
applying, with a bonding structure, a pressure to a portion of the layer of the bonding material between the second surface of the first substrate and the first surface of the third substrate after the aligning of the first surface of the third substrate to the second surface of the first substrate, and
applying, while the pressure is applied, a voltage between the layer of the bonding material on the second surface of the first substrate and the third substrate.

20. The vacuum cell of claim 18, wherein the method further comprises applying, prior to forming the layer of the bonding material on the first surface of the first substrate, stress compensation to the first substrate to correct a curvature of the first substrate.
